(19) United States
(12) Patent Application Publication
(10) Pub. No.: US 2025/0293163 A1
(43) Pub. Date: Sep. 18, 2025

(54) MULTILAYER CONNECTION STRUCTURE AND MANUFACTURING METHOD THEREOF, SEMICONDUCTOR DEVICE

(71) Applicant: SwaySure Technology Co., Ltd., Shenzhen (CN)

(72) Inventor: JINGHAO WANG, Shenzhen (CN)

(21) Appl. No.: 19/057,397

(22) Filed: Feb. 19, 2025

(30) Foreign Application Priority Data
Mar. 12, 2024 (CN) 202410294629.5
Mar. 12, 2024 (CN) 202420486148.X

(51) Int. Cl. H01L 23/532; H01L 21/768; H01L 23/528

(52) U.S. Cl. CPC H01L 23/53295; H01L 21/76877; H01L 23/528; H01L 23/5283

(57) ABSTRACT

A multilayer connection structure includes a laminated structure, including a plurality of lead wire film layers and at least one insulation film layer, the plurality of the lead wire film layers and the at least one insulation film layer are alternately provided in a vertical direction, and each of the plurality of the lead wire film layers includes an actual lead wire pattern portion at least; a plurality of interconnection through holes horizontally spaced apart expose the actual lead wire pattern portion of the at least one of the plurality of lead wire film layers, in the laminated structure, each of the plurality of interconnection through holes penetrates through at least all of film layers above a bottommost lead wire film layer; and interconnection conductors, filled in the plurality of interconnection through holes.

### CROSS-REFERENCE TO RELATED APPLICATIONS

This application claims priority to Chinese Patent Application No. 202410294629.5, filed on Mar. 12, 2024, and Chinese Patent Application No. 202420486148.X, filed on Mar. 12, 2024, the entire disclosures of which are hereby incorporated herein by reference.

### TECHNICAL FIELD

The present disclosure belongs to the field of semiconductor technology, and specifically relates to a multilayer connection structure and a manufacturing method thereof, a semiconductor device.

### BACKGROUND

Currently, semiconductor technology is developing rapidly, and in semiconductor devices, semiconductor devices are becoming denser, and the number of layers of lead wire film layers in the interconnection structure is becoming more and more, which makes the connection relationship between the lead wire film layers and the way of lead wire film layers being lead to outside become more and more complicated, and thus it will consume a great deal of production costs and waste production capacity.

### SUMMARY

There are provided a multilayer connection structure and a manufacturing method thereof, a semiconductor device, according to embodiments of the present disclosure. The technical solution is as below.

A first aspect of the present disclosure provides a multilayer connection structure, which includes:
a laminated structure, comprising a plurality of lead wire film layers and at least one insulation film layer, wherein the plurality of the lead wire film layers and the at least one insulation film layer are alternately provided in a vertical direction, and each of the plurality of the lead wire film layers includes an actual lead wire pattern portion at least;
a plurality of interconnection through holes horizontally spaced apart, wherein the plurality of interconnection through holes expose the actual lead wire pattern portion of the at least one of the plurality of lead wire film layers, and positions of the lead wire film layers where actual lead wire pattern portions exposed by at least two of the plurality of interconnection through holes are located are not totally identical, wherein in the laminated structure, each of the plurality of interconnection through holes penetrates through at least all of film layers above a bottommost lead wire film layer; and
interconnection conductors, filled in the plurality of interconnection through holes.

A second aspect of the present disclosure provides a semiconductor device, comprising a substrate and at least one multilayer connection structure mentioned above, the multilayer connection structure is formed on the substrate.

A third aspect of the present disclosure provides a method of manufacturing a multilayer connection structure, which includes:
alternately providing a lead wire film layer and an insulation film layer on a substrate in a vertical direction to form a laminated structure, a plurality of lead wire film layers are provided, at least one insulation film layer is provided, and each of the plurality of lead wire film layers includes an actual lead wire pattern portion at least;
after forming a topmost film layer of the laminated structure, patterning the laminated structure using an etching process to form a plurality of interconnection through holes horizontally spaced apart, wherein in the laminated structure, the plurality of interconnection through holes penetrate through at least all of film layers above a bottommost lead wire film layer and expose the actual lead wire pattern portion of at least one lead wire film layer, and positions of the lead wire film layers where actual lead wire pattern portions exposed by at least two of the plurality of interconnection through holes are located are not totally identical; and
filling each interconnection through hole with conductor material to form an interconnection conductor within each interconnection through hole.

### BRIEF DESCRIPTION OF THE DRAWINGS

The accompanying drawings herein are incorporated into and form a part of the specification, illustrate embodiments consistent with the present disclosure, and are used in conjunction with the specification to explain the principles of the present disclosure. Obviously, the accompanying drawings in the following description are only some of the embodiments of the present disclosure, and others may be obtained from these drawings without creative labor for those skilled in the art.

FIGS. 1a and 1b are schematic structural views of multilayer connection structures shown in different related technologies, respectively.

FIGS. 2 to 5 are schematic structural views of the multilayer connection structure shown in different embodiments of the present disclosure, respectively.

FIG. 6 is a schematic structural view after aperture treatment of a laminated structure as described in an embodiment of the present disclosure.

FIG. 7 is a schematic structural view of the laminated structure including an actual lead wire pattern portion and a virtual pattern portion as described in an embodiment of the present disclosure.

FIG. 8 is a schematic structural view after aperture treatment of the laminated structure shown in FIG. 7.

FIG. 9 is a schematic structural view of the multilayer connection structure described in another embodiment of the present disclosure.

FIGS. 10 to 13 are schematic structural views of the planar relationship between the interconnection conductor and the pattern portion in different embodiments of the present disclosure, respectively.

FIGS. 14 and 15 are schematic structural views of the multilayer connection structure described in other embodiments of the present disclosure, respectively.

FIGS. 16 to 19 are schematic structural views corresponding to different steps completed in manufacturing the multilayer connection structure in embodiments of the present disclosure, respectively.

### DETAILED DESCRIPTION OF THE EMBODIMENTS

Example embodiments will now be described more fully with reference to the accompanying drawings. However, the example embodiments are implemented in a variety of forms and should not be construed as being limited to the examples set forth herein; rather, the provision of these embodiments allows the present disclosure to be more comprehensive and complete and conveys the idea of the example embodiments in a comprehensive manner to those skilled in the art.

In addition, the described features, structures, or characteristics may be combined in one or more embodiments in any suitable manner. In the following description, many specific details are provided thereby giving a full understanding of the embodiments of the present disclosure. However, those skilled in the art will realize that it is possible to practice the technical embodiments of the present disclosure without one or more of the specific details, or that other methods, components, devices, steps, etc. may be employed. In other cases, the well-known methods, devices, implementations, or operations are not shown or described in detail to avoid blurring aspects of the present disclosure.

The present disclosure is described in further detail below in connection with the accompanying drawings and specific embodiments. It should be noted herein that the technical features involved in the various embodiments of the present disclosure described below may be combined with each other as long as they do not constitute a conflict with each other. The embodiments described below by reference to the accompanying drawings are exemplary and are intended to be used for explaining the present disclosure and are not to be construed as a limitation of the present disclosure.

As semiconductor technology continues to evolve, semiconductor devices are becoming denser in semiconductor devices, which makes the interconnections between lead wire film layers and the interconnections between lead wire film layers and other circuits more and more complex, thereby increasing the types of interconnection conductors required in the stereo stacking process.

It should be understood that an interconnection conductor refers to a structure with conductive properties for connecting different conductive devices, e.g., an interconnection conductor that realizes a connection between different lead wire film layers, a connection between different lead wires in each lead wire film layer, a connection between a lead wire film layer and an external working circuit, and so on.

Further, the interconnection conductor that realizes the connection between the different lead wire film layers and the interconnection conductor that realizes the connection between the lead wire film layers and the external working circuits may be defined as interconnection conductors interconnected vertically, and the interconnection conductor that realizes the connection between the different lead wires in each lead wire film layer may be an interconnection conductor interconnected horizontally.

In the semiconductor device, there are a plurality of types of the interconnection conductors vertically interconnected, and if lead wires, which are correspondingly connected, of a plurality of vertically interconnected interconnection conductors are located in different lead wire film layers, these vertically interconnected interconnection conductors are of different types. Specifically, reference may be made to the laminated structure shown in FIG. 1a for illustration, in FIG. 1a, four types of vertically interconnected interconnection conductors are present in the laminated structure, namely a first interconnection conductor HL1, a second interconnection conductor HL2, a third interconnection conductor HL3, and a fourth interconnection conductor HL4. The first interconnection conductor HL1 connects the lead wire 10 in the first lead wire film layer 1a and the lead wire 10 in the second lead wire film layer 1b, the second interconnection conductor HL2 connects the lead wire 10 in the first lead wire film layer 1a and the lead wire 10 in the third lead wire film layer 1c, one end of the third interconnection conductor HL3 connects the lead wire 10 in the first lead wire film layer 1a, another end of the third interconnection conductor HL3 extends in the direction away from the first lead wire film layer 1a and penetrates through the laminated structure, to be lead outwardly to connect the external working circuit (not shown in the figure). An end of the fourth interconnection conductor HL4 connects the lead wire 10 in the fourth lead wire film layer 1d, and another end of the fourth interconnection conductor HL4 extends in the direction away from the fourth lead wire film layer 1d and penetrates through the laminated structure, to be lead outwardly to connect the external working circuit.

It should be noted that FIG. 1a is only used to illustrate that multiple types of vertically interconnected interconnection conductors will be present in the laminated structure, and does not necessarily mean that the laminated structure will necessarily include vertically interconnected interconnection conductors of the types shown in FIG. 1a, i.e., the laminated structure may include all, some, or none of the vertically interconnected interconnection conductors of the types shown in FIG. 1a, depending on the product requirements for designing the vertically interconnected interconnection conductors of different types. In addition, the number of vertically interconnected interconnection conductors, the number of layers of the lead wire film layer, the number of lead wires in the lead wire film layer, etc. are not limited to those shown in FIG. 1a, and can be designed according to the actual situation.

Referring to FIG. 1a, the vertically interconnected interconnection conductors are usually designed to be located between two structures to be connected, so that the vertically interconnected interconnection conductors of different types need to be separately manufactured, and therefore, as the lead wire film layers become denser and the types of vertically interconnected interconnection conductors required become more and more, the production cost becomes more and more expensive, and the production capacity is wasted.

In addition, when the number of layers of the lead wire film layers 1 is larger and there are lead wires 10 in two adjacent lead wire film layers that need to be connected by vertically interconnected interconnection conductors HL, such as that shown in FIG. 1b, each layer of vertically interconnected interconnection conductors HL needs to be separately manufactured, so that holes (which are used to accommodate interconnection conductors) need to be prepared layer by layer when fabricating the corresponding interconnection conductors HL for each layer, resulting in the number of process times increasing with the number of layers of the lead wire film layers 1 and increasing the production cost accordingly.

Embodiments of the present disclosure provide a multilayer connection structure, which can be applied in a semiconductor device. The multilayer connection structure may include a laminated structure, the laminated structure may include a plurality of lead wire film layers and a plurality of insulation film layers, and the lead wire film layers and the insulation film layers are provided alternately in a vertical direction, that is, the laminated structure may include a structure in which the lead wire film layers, the insulation film layers, the lead wire film layers, the insulation film layers, etc. are repeatedly and alternately laminated. The multilayer connection structure may also include a plurality of interconnection through holes horizontally spaced apart and interconnection conductors filled in each interconnection through hole, and different types of interconnection conductors are included in the plurality of interconnection conductors of the multilayer connection structure, but without limitation, the plurality of interconnection conductors of the multilayer connection structure may also include interconnection conductors of the same type, but whether the interconnection conductors of the same type are included may be designed according to the actual situation.

The multilayer connection structure of an embodiment of the present disclosure is described in detail below in conjunction with the accompanying drawings.

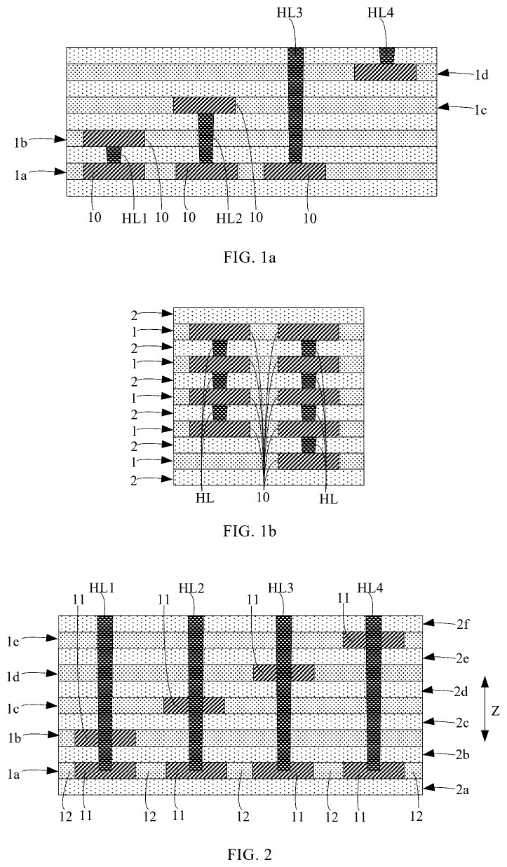

Referring to FIG. 2, the laminated structure may include a first insulation film layer 2a, a first lead wire film layer 1a, a second insulation film layer 2b, a second lead wire film layer 1b, a third insulation film layer 2c, a third lead wire film layer 1c, a fourth insulation film layer 2d, a fourth lead wire film layer 1d, a fifth insulation film layer 2e, a fifth lead wire film layer 1e, and a sixth insulation film layer 2f, laminated in sequence in the vertical direction Z.

In the laminated structure of the present disclosure, the bottommost film layer (i.e.: the first formed film layer) may be an insulation film layer, e.g.: the first insulation film layer 2a shown in FIG. 2, to isolate the bottommost lead wire film layer (e.g.: the first lead wire film layer 1a shown in FIG. 2) from external other circuits, and also to protect the bottommost lead wire film layer, but not limited to this. The bottommost film layer may also be a lead wire film layer, to facilitate the connection with other circuit structures, which may be designed according to the actual needs. In addition, the topmost film layer (the last formed film layer) can be an insulation film layer, for example, the sixth insulation film layer 2f shown in FIG. 2, to isolate the topmost lead wire film layer (e.g., the fifth lead wire film layer 1e shown in FIG. 2) from the external other circuits, and also to protect the topmost lead wire film layer, but not limited to this. The topmost film layer may also be a lead wire film layer to facilitate connection with other circuit structures, which may be designed according to actual needs.

It should be understood that the insulation film layer is not limited to the aforementioned multilayer, when two lead wire film layers are provided, one insulation film layer can also be provided, and is located between the two lead wire film layers. Furthermore, when two lead wire film layers are provided, a plurality of the insulation film layers may also be provided, such as: the insulation film layer, the lead wire film layer, the insulation film layer, and the lead wire film layer are provided sequentially in alternating order, or the lead wire film layer, the insulation film layer, the lead wire film layer, the insulation film layer, and the insulation film layer are provided sequentially in alternating order, and so on, which may be designed according to actual needs.

In some other embodiments, more than three lead wire film layers may be provided, e.g., referencing to the five layers shown in FIG. 2, but not limited thereto, and may be three, four, or more than five layers, etc., and by providing more than three lead wire film layers, the diversity of design of the interconnection structure may be realized so as to improve the interconnection density. When the interconnection structure in the present disclosure is applied in the wiring of a three-dimensional storage structure, the cost of manufacturing the wiring of the three-dimensional storage structure can be reduced.

In embodiments of the present disclosure, each lead wire film layer may include at least a plurality of pattern portions, and it should be understood that the material of the pattern portions may be a conductor material, that is to say, the pattern portions themselves may have conductive properties. For example, the material of the pattern portion may include one or more metal conductive materials, such as aluminum, copper, tungsten, and so on, but not limited to this, but also maybe other non-metallic conductive materials such as graphite, or semiconductor materials such as polysilicon, and so on, will not be described herein.

The plurality of pattern portions of each lead wire film layer may include at least an actual lead wire pattern portion 11, the actual lead wire pattern portion 11 refers to a portion that is actually used in the circuit structure for realizing a function such as signal transmission. For example, the actual lead wire pattern portion 11 in the lead wire film layer may include one or more of a word line, a bit line, a capacitor pole plate, a ground line, a bridge line, a gate, a source-drain, etc., which may be designed according to the actual needs without any specific limitation herein.

In addition, the number and the arrangement of actual lead wire pattern portions 11 in each lead wire film layer may also be designed according to the actual situation and are not described in detail herein.

In some embodiments, each lead wire film layer may include an insulating isolation portion 12 in addition to a pattern portion having conductive properties, and the insulating isolation portion 12 may be formed in a region of the lead wire film layer where the pattern portion is not required to be set, e.g., the insulating isolation portion 12 may be formed in a gap between adjacent pattern portions to realize insulating isolation between pattern portions of each lead wire film layer at a specific position, and the insulating isolation portion 12 may also be formed at an edge position of the entire lead wire film layer.

The top surface of the insulating isolation portion 12 may be flush with the top surface of the pattern portion to ensure the flatness of the surface of the lead wire film layer, thereby facilitating the execution of the subsequent film layer process and ensuring the flatness of the subsequent film layer.

By way of example, the material of the insulating isolation portion 12 may be the same as the material of the insulation film layer, but is not limited thereto and may not be the same. And in embodiments of the present disclosure, the material of the insulation film layer and the insulating isolation portion 12 may include one or more of silicon nitride, silicon oxide, silicon nitride oxide, etc., or may be a low-k (low dielectric constant) dielectric material to reduce crosstalk between adjacent lead wire film layers and interconnection conductors, but is not limited to this, and other insulating materials may be used.

It should be noted that in the multilayer connection structure of the present disclosure: each interconnection conductor may be connected to the actual lead wire pattern portion 11 of the at least one lead wire film layer according to the actual design, and positions of the lead wire film layers where actual lead wire pattern portions 11 correspondingly connected to the at least two interconnection conductors are located are not at exactly the same, i.e., there are different types of vertically interconnected interconnection conductors in the multilayer connection structure of the present disclosure. By way of example, in some embodiments, as shown in FIG. 2, in the multilayer connection structure: the first interconnection conductor HL1, the second interconnection conductor HL2, the third interconnection conductor HL3, and the fourth interconnection conductor HL4 are correspondingly connected to the same number of lead wire film layers where the actual lead wire pattern portions 11 are located, but the actual lead wire pattern portions 11 are located at partially different positions, i.e., the number of lead wire film layers where the actual lead wire pattern portion 11 correspondingly connected to the first interconnection conductor HL1, the second interconnection conductor HL2, the third interconnection conductor HL3, and the fourth interconnection conductor HL4 are located is two, and the actual lead wire pattern portion correspondingly connected to the first interconnection conductor HL1 includes the actual lead wire pattern portion 11 in the first lead wire film layer 1a and the actual lead wire pattern portion 11 in the second lead wire film layer 1b, and the actual lead wire pattern portion correspondingly connected to the second interconnection conductor HL2 includes the actual lead wire pattern portion 11 in the first lead wire film layer 1a and the actual lead wire pattern portion 11 in the third lead wire film layer 1c. The actual lead wire pattern portion correspondingly connected to the third interconnection conductor HL3 includes the actual lead wire pattern portion 11 in the first lead wire film layer 1a and the actual lead wire pattern portion 11 in the fourth lead wire film layer 1d, and the actual lead wire pattern portion correspondingly connected to the fourth interconnection conductor HL4 includes the actual lead wire pattern portion 11 in the first lead wire film layer 1a and the actual lead wire pattern portion 11 in the fifth lead wire film layer 1e. That is, the first interconnection conductor HL1, the second interconnection conductor HL2, the third interconnection conductor HL3, and the fourth interconnection conductor HL4 in the multilayer connection structure shown in FIG. 2 are different types of interconnection conductors.

In other embodiments, with reference to FIG. 3, in the multilayer connection structure: there are interconnection conductors correspondingly connected to the actual lead wire pattern portions 11 that are located in the same number of lead wire film layers, but in completely different positions, e.g., the first interconnection conductor HL1 and the second interconnection conductor HL2, and there are interconnection conductors correspondingly connected to the actual lead wire pattern portions 11 that are located in the same number of lead wire film layers, but in completely different positions, e.g., the third interconnection conductor HL3 and the fourth interconnection conductor HL4, there are interconnection conductors correspondingly connected to the actual lead wire pattern portions 11 that are located in the different number of lead wire film layers, but in partially different positions, such as: the first interconnection conductor HL1 and the third interconnection conductor HL3, the first interconnection conductor HL1 and the fourth interconnection conductor HL4, or the second interconnection conductor HL2 and the fourth interconnection conductor HL4.

It should be noted that the multilayer connection structure in the present disclosure is not limited to the designs shown in FIGS. 2 and 3, and other designs may be made according to actual needs, which will not be exemplified herein.

In a specific embodiment of the present disclosure, in the multilayer connection structure: each interconnection conductor penetrates through at least all the film layers above the bottommost lead wire film layer in the laminated structure, i.e.: each interconnection conductor extends in the direction from the topmost end of the laminated structure (farthest end from the substrate required in the fabrication process) to the bottommost end of the laminated structure (nearest end from the substrate required in the fabrication process), to at least penetrate through all the film layers above the bottommost lead wire film layer in the laminated structure. It should be understood that all of the film layers mentioned herein include an insulation film layer and a lead wire film layer, and that when each interconnection conductor penetrates through at least all the film layers above the bottommost lead wire film layer in the laminated structure, each interconnection conductor can be realized to be connected to a corresponding actual lead wire pattern portion 11 of the corresponding lead wire film layer, i.e., in positive projection, the interconnection conductor is not detached from a corresponding actual lead wire pattern portion of the corresponding lead wire film layer, the interconnection conductor is considered to be connected to the corresponding actual lead wire pattern portion of the corresponding lead wire film layer.

For example, with reference to FIGS. 2 and 3, the first interconnection conductor HL1, the second interconnection conductor HL2, the third interconnection conductor HL3, and the fourth interconnection conductor HL4 may penetrate through all the film layers above the bottommost lead wire film layer (i.e., the first lead wire film layer 1a). In other words, the first interconnection conductor HL1, the second interconnection conductor HL2, the third interconnection conductor HL3, and the fourth interconnection conductor HL4 may penetrate through the sixth insulation film layer 2f, the fifth lead wire film layer 1e, the fifth insulation film layer 2e, the fourth lead wire film layer 1d, the fourth insulation film layer 2d, the third lead wire film layer 1c, the third insulation film layer 2c, the second lead wire film layer 1b, and the second insulation film layer 2b.

Since each interconnection conductor in the multilayer connection structure needs to penetrate through all the film layers above the bottommost lead wire film layer in the laminated structure to realize connection with the actual lead wire pattern portion 11 of the corresponding lead wire film layer, it can be seen that all the interconnection conductors in the multilayer connection structure of the present disclosure are formed after the production of the topmost film layer of the laminated structure is completed, such design facilitates the simultaneous production of different types of interconnection conductors in the multilayer connection structure. Compared to the structural scheme in which different types of interconnection conductors need to be manufactured separately as shown in FIG. 1a, and the structural scheme in which the multilayer interconnection conductors are manufactured layer by layer as shown in FIG. 1b, the multilayer connection structure of the present disclosure can reduce the cost of the multilayer connection structure, and reduce the waste of production capacity.

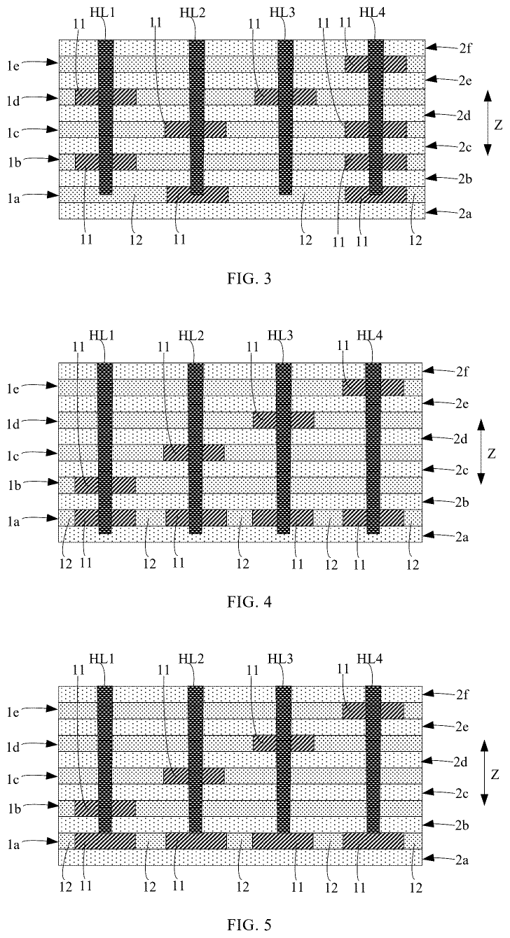

It is to be noted that each interconnection conductor is not limited to penetrating through all film layers above the bottommost lead wire film layer in the laminated structure, but may also penetrate through the bottommost lead wire film layer, such as shown in FIG. 4, the first interconnection conductor HL1, the second interconnection conductor HL2, the third interconnection conductor HL3, and the fourth interconnection conductor HL4 penetrate through the first lead wire film layer 1a (i.e.: the bottommost lead wire film layer) in addition to the sixth insulation film layer 2f, the fifth lead wire film layer 1e, the fifth insulation film layer 2e, the fourth lead wire film layer 1d, the fourth insulation film layer 2d, the third lead wire film layer 1c, the third insulation film layer 2c, the second lead wire film layer 1b, the second insulation film layer 2b, but not limited to. Each interconnection conductor, in addition to penetrating through all the film layers above the first lead wire film layer 1a in the laminated structure, may also extend into the first lead wire film layer 1a, such as shown in FIGS. 2 and 3, or each interconnection conductor only penetrates through all the film layers above the first lead wire film layer 1a in the laminated structure, and does not penetrate through the first lead wire film layer 1a, but merely extends to the top surface of the first lead wire film layer 1a, i.e.: is in contact with the top surface of the first lead wire film layer 1a, such as shown in FIG. 5.

In some embodiments, the positive projection of the interconnection conductor of the present disclosure in the vertical direction Z may be located within the actual lead wire pattern portion 11 to which it is correspondingly connected, and since it is mentioned above that the interconnection conductor penetrates through at least all the film layers above the bottommost lead wire film layer, when the actual lead wire pattern portion 11 to which the interconnection conductor is correspondingly connected includes the actual lead wire pattern portion 11 above the bottommost lead wire film layer, then the interconnection conductor at least penetrates through the actual lead wire pattern portion 11 connected to the interconnection conductor and located above the bottommost lead wire film layer, that is, the present disclosure can make the interconnection conductor to be in contact with the actual lead wire pattern portion 11 corresponding to the interconnection conductor and located above the bottommost lead wire film layer in a penetrating manner, thereby realizing the connection of the interconnection conductor with the actual lead pattern part 11 corresponding to the interconnection conductor and located above the bottommost lead wire film layer, which can reduce the difficulty of connection of the interconnection conductor with the actual lead wire pattern portion 11, and also increase the contact area between the interconnection conductor and the actual lead wire pattern portion 11 to ensure the reliability of the contact between the interconnection conductor and the actual lead wire pattern portion 11.

By way of example, referring to FIG. 3, the first interconnection conductor HL1 correspondingly penetrates through the actual lead wire pattern portions 11 of the fourth lead wire film layer 1d and the second lead wire film layer 1b to realize connection of the actual lead wire pattern portion 11 of the fourth lead wire film layer 1d with the actual lead wire pattern portion 11 of the second lead wire film layer 1b. The second interconnection conductor HL2 correspondingly penetrates through the actual lead wire pattern portion 11 of the third lead wire film layer 1c and extends to the actual lead wire pattern portion 11 of the first lead wire film layer 1a to realize connection of the actual lead wire pattern portion 11 of the third lead wire film layer 1c with the actual lead wire pattern portion 11 of the first lead wire film layer 1a. The third interconnection conductor HL3 correspondingly penetrates through the actual lead wire pattern portion 11 of the fourth lead wire film layer 1d, and the top surface of the third interconnection conductor HL3 can be connected to external working circuits to realize connection of the actual lead wire pattern portion 11 of the fourth lead wire film layer 1d with external working circuits. The fourth interconnection conductor HL4 correspondingly penetrates through the actual lead wire pattern portions 11 of the fifth lead wire film layer 1e, the third lead wire film layer 1c, and the second lead wire film layer 1b, and extends to the actual lead wire pattern portion 11 of the first lead wire film layer 1a, to realize connection of the actual lead wire pattern portions 11 of the fifth lead wire film layer 1e, the third lead wire film layer 1c, the second lead wire film layer 1b and the first lead wire film layer 1a.

When the actual lead wire pattern portion correspondingly connected to the interconnection conductor includes an actual lead wire pattern portion 11 in the bottommost lead wire film layer, as shown in FIG. 4, the interconnection conductor may penetrate through the actual lead wire pattern portion 11 of the bottommost lead wire film layer, or, as shown in FIGS. 2 and 3, it may not completely penetrate through the actual lead wire pattern portion 11 of the bottommost lead wire film layer, but may only extend to an inside of the actual lead wire pattern portion 11 of the bottommost lead wire film layer. The two connection methods can increase the contact area between the interconnection conductor and the actual lead wire pattern portion 11 of the bottommost lead wire film layer to ensure the contact stability thereof, but is not limited to this. As shown in FIG. 5, the interconnection conductor can also be extended only to the top surface of the actual lead wire pattern portion 11 of the bottommost lead wire film layer, i.e., just in contact with the top surface of the actual lead wire pattern portion 11 of the bottommost lead wire film layer to realize connection of the interconnection conductor with the actual lead wire pattern portion 11 of the bottommost lead wire film layer.

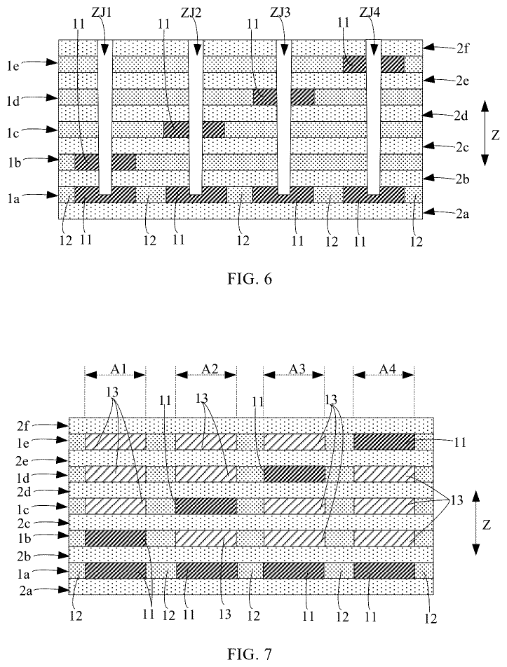

In the present disclosure, the interconnection conductors are formed by first forming interconnection through holes in corresponding regions of the laminated structure, for example, with reference to FIG. 6, a first interconnection through hole ZJ1, a second interconnection through hole ZJ2, a third interconnection through hole ZJ3, and a fourth interconnection through hole ZJ4 may be formed in the corresponding region of the laminated structure, and then the interconnection through hole is filled with the conductor material to form an interconnection conductor in the interconnection through hole. For example, as shown in FIG. 2, the first interconnection conductor HL1 may be formed within the first interconnection through hole ZJ1, the second interconnection conductor HL2 may be formed within the second interconnection through hole ZJ2, the third interconnection conductor HL3 may be formed within the third interconnection through hole ZJ3, and the fourth interconnection conductor HL4 may be formed within the fourth interconnection through hole ZJ4.

Since the interconnection conductors of the present disclosure are required to penetrate through at least all the film layers above the bottommost lead wire film layer in the laminated structure, it can be noted that the present disclosure, when designing the interconnection through holes of the multilayer connection structure, requires the preparation of a plurality of interconnection through holes horizontally spaced apart, each of which penetrates through at least all the film layers above the bottommost lead wire film layer in the laminated structure and exposes the actual lead wire pattern portion 11 of the at least one lead wire film layer.

Specifically as shown in FIG. 6, the first interconnection through hole ZJ1 exposes the actual lead wire pattern portions 11 of the first lead wire film layer 1a and the second lead wire film layer 1b, the second interconnection through hole ZJ2 exposes the actual lead wire pattern portions 11 of the first lead wire film layer 1a and the third lead wire film layer 1c; the third interconnection through hole ZJ3 exposes the actual lead wire pattern portions 11 of the first lead wire film layer 1a and the fourth lead wire film layer 1d; the fourth interconnection through hole ZJ4 exposes the actual lead wire pattern portions 11 of the first lead wire film layer 1a and the fifth lead wire film layer 1e, such that in the subsequent process of filling the interconnection through hole with the conductor material to form the interconnection conductor, the conductor material in the interconnection through hole can be in contact with the correspondingly exposed actual lead wire pattern portion 11, i.e.: realizing connection of the interconnection conductor with the corresponding actual lead wire pattern portion 11, e.g., in combination with the FIGS. 2 and 6.

It should be understood that since the interconnection conductors are formed by filling the interconnection through holes with conductor material, the design of the interconnection conductors in terms of extension length, shape, area, etc., is related to the design of the interconnection through hole, i.e. the design of the interconnection through holes is matched to the design of the interconnection conductors. For example, if you want to realize the interconnection conductor penetrates through the bottommost lead wire film layer in addition to penetrating through all the film layers above the bottommost lead wire film layer of the laminated structure, then when designing the interconnection through holes, it needs to design the interconnection through hole penetrating through the bottommost lead wire film layer in addition to penetrating through all the film layers above the bottommost lead wire film layer in the laminated structure. If you want to realize that the interconnection conductor can extend into the bottommost lead wire film layer in addition to penetrating through all the film layers above the bottommost lead wire film layer in the laminated structure. When designing the interconnection through hole, it needs to design the interconnection through hole to extend into the bottommost lead wire film layer in addition to penetrating through all the film layers above the bottommost lead wire film layer in the laminated structure, and so on, no specific examples will be given here.

In some embodiments, interconnection through holes corresponding to different types of interconnection conductors may be prepared simultaneously by one-time molding, e.g., after forming the topmost film layer in the laminated structure, the laminated structure may be patterned by a one-time etching process to form a plurality of interconnection through holes horizontally spaced apart required in the laminated structure, and since the interconnection conductors are of different types, the interconnection conductors of different types correspond to interconnection through holes of different types. Specifically, positions of the lead wire film layers where the actual lead wire pattern portions 11 exposed by the interconnection through holes of different types of interconnection conductors in the vertical direction Z are located are not identical, e.g., positions of the lead wire film layers where the actual lead wire pattern portions 11 exposed by the first interconnection through hole ZJ1, the second interconnection through hole ZJ2, the third interconnection through hole ZJ3, and the fourth interconnection through hole ZJ4 shown in FIG. 6 in the vertical direction Z are located are partially different. As a result, the number of processes is reduced and the production cost is reduced.

It is to be noted that a one-time molding process refers to a process technology in which the entire molding process can be completed by a single operation during the preparation of the interconnection through hole. The present disclosure adopts the one-time molding process to prepare interconnection through holes corresponding to the different types of interconnection conductors in addition to one-time preparing interconnection through holes corresponding to the same type of interconnection conductors, and therefore, the machining time and cost can be reduced, the productivity can be improved, and the machining accuracy and quality can be ensured as well.

It can be understood that when a plurality of interconnection through holes required for a multilayer connection structure are prepared simultaneously by a one-time etching process, the etching process conditions (including gases used for etching, process parameters, etc.) can be adaptively adjusted with different etching depths and different materials of the etched film layers, but the etching process is still continuously or quasi-continuously carried out, and thus even if the etching process conditions are adaptively adjusted at different stages of the etching process, it still belongs to a one-time etching process.

By way of example, embodiments of the present disclosure may employ an etching process to open holes in the laminated structure to form the interconnection through holes referred to in embodiments of the present disclosure, the etching process may be anisotropic etching, and further may be dry etching, but is not limited to this, and other etching preparation methods may be employed while ensuring etching accuracy of the interconnection through holes under the same pattern density.

Since positions of the lead wire film layers where the actual lead wire pattern portions 11 correspondingly connected to different types of interconnection conductors are located are not totally identical, when the interconnection through holes of different types of interconnection conductors are manufactured using the one-time molding process, there are differences in the laminated film layers penetrated through by the interconnection through holes corresponding to the different types of interconnection conductors in the vertical direction Z.

For example, in some embodiments, the number of pattern portions in the laminated film layers penetrated through by the interconnection through holes corresponding to the different types of interconnection conductors in the vertical direction Z is not identical, as shown in FIG. 3, the pattern portions penetrated through by the first interconnection through holes ZJ1 and the second interconnection through holes ZJ2 are two actual lead wire pattern portions 11, the pattern portion penetrated through by the third interconnection through holes ZJ3 is one actual lead wire pattern portion 11, and the pattern portions penetrated through by the fourth interconnection through holes ZJ4 are 4 actual lead wire pattern portions 11. It should be understood that since the number of total film layers penetrated through by each interconnection through hole in the vertical direction Z is the same, thus the number of pattern portions penetrated through by each interconnection through hole in the vertical direction Z is not exactly the same, the number of the insulating isolation portions 12 penetrated through is not exactly the same.

In other embodiments, the number of pattern portions in the laminated film layer penetrated through by the interconnection through holes corresponding to different types of interconnection conductors in the vertical direction Z may be the same, but the positions of the lead wire film layer where the pattern portions are located are not identical, e.g., with reference to FIG. 6, the number of insulating isolation portions 12 and the number of actual lead wire pattern portions 11 penetrated through by the first interconnection through holes ZJ1, the second interconnection through holes ZJ2, the third interconnection through holes ZJ3, and the fourth interconnection through holes ZJ4 are the same, but the positions of the lead wire film layers where the actual lead wire pattern portions 11 are located are different, i.e., the laminated film layers penetrated through by the first interconnection through hole ZJ1 from top to bottom include the sixth insulation film layer 2f, an insulating isolation portion 12 of the fifth lead wire film layer 1e, the fifth insulation film layer 2e, an insulating isolation portion 12 of the fourth lead wire film layer 1d, a fourth insulation film layer 2d, a third insulating isolation portion 12 of the third lead wire film layer 1c, the third insulation film layer 2c, the actual lead wire pattern portion 11 of the second lead wire film layer 1b, and the second insulation film layer 2b. The laminated film layers penetrated through by the second interconnection through hole ZJ2 from top to bottom include the sixth insulation film layer 2f, the insulating isolation portion 12 of the fifth lead wire film layer 1e, the fifth insulation film layer 2e, the insulating isolation portion 12 of the fourth lead wire film layer 1d, the fourth insulation film layer 2d, the actual lead wire pattern portion 11 of the third lead wire film layer 1c, the third insulation film layer 2c, the insulating isolation portion 12 of the second lead wire film layer 1b, and the second insulation film layer 2b. The laminated film layers penetrated through by the third interconnection through hole ZJ3 from top to bottom include the sixth insulation film layer 2f, the insulating isolation portion 12 of the fifth lead wire film layer 1e, the fifth insulation film layer 2e, the actual lead wire pattern portion 11 of the fourth lead wire film layer 1d, the fourth insulation film layer 2d, the insulating isolation portion 12 of the third lead film layer 1c, the third insulation film layer 2c, the insulating isolation portion 12 of the second lead film layer 1b, and the second insulation film layer 2b. The laminated film layers penetrated through by the fourth interconnection through hole ZJ4 includes the sixth insulation film layer 2f, the actual lead wire pattern portion 11 of the fifth lead wire film layer 1e, the fifth insulation film layer 2e, the insulating isolation portion 12 of the fourth lead wire film layer 1d, the fourth insulation film layer 2d, the insulating isolation portion 12 of the third insulation film layer 1c, the third insulation film layer 2c, the insulating isolation portion 12 of the second insulation film layer 1b, and the second insulation film layer 2b.

The etching rate is not constant in the hole etching depth, which can be understood as follows: under the same process conditions, the deeper the hole is, the slower it is etched. Furthermore, due to the differences in the laminated film layers penetrated through by the interconnection through holes corresponding to different types of interconnection conductors in the vertical direction Z, i.e., the number and/or position of the pattern portions are not exactly the same and the materials of the pattern portions and the insulating isolation portions 12 are not the same, making the etching rates of the pattern portions and the insulating isolation portions 12 not the same, therefore, when the etching process is used to produce interconnection through holes of different types of interconnection conductors, since the film layers penetrated through by the interconnection through holes corresponding to the different types of interconnection conductors are not exactly the same, thus it is easy to make some of the interconnection through holes produced have different depths of etching at the same time, which results in the interconnection through holes corresponding to the different types of interconnection conductors being prone to under-etching, or over-etching eventually, and it is prone to serious etching load effect, high difficulty in etching control, and affecting the yield.

In some embodiments, when different types of interconnection through holes required for the multilayer connection structure are prepared simultaneously by one-time etching process, the etching process conditions (including the gas used for etching, the process parameters, etc.) may be adaptively adjusted with the different etching depths and the different materials of the film layers to be etched, but the etching process is still carried out continuously or quasi-continuously, and therefore even if the etching process conditions are adaptively adjusted at different stages of the etching process, it also belongs to the scope of the one-time etching process. In this etching process, when the same lead wire film layer is etched, the two interconnection through holes penetrate through different film layer materials, for example, one of the two interconnection through holes penetrates through the pattern portion, and another of the two interconnection through holes penetrates through the insulating isolation portion 12, and the pattern portion and the insulating isolation portion 12 are not of the same material, which makes the etching rates of the pattern portion and the insulating isolation portion 12 not the same, resulting in that when etching is completed on one interconnection through hole of the lead wire film layer, the other interconnection through hole has an over-etched or under-etched defect. The defects are superimposed with the increase of the film layers of the laminated structure and the increase of the etching depth of the interconnection through holes, thereby affecting the yield.

In order to solve the above problem, the embodiments of the present disclosure, when fabricating a multilayer connection structure including different types of interconnection conductors, may utilize the design of the virtual pattern portion 13 to make the laminated film layers penetrated through by the interconnection through holes corresponding to each interconnection conductor in the vertical direction Z the same, i.e., the number of pattern portions and the layout position of the pattern portions in the laminated film layers are exactly the same, so as to ensure the homogeneity of each interconnection through hole during etching, i.e., reducing the problem of under-etching or over-etching of some interconnection through holes, to improve the etching load effect, reduce the difficulty of etching control, and improve the machining yield.

Specifically, the pattern portion of the at least one lead wire film layer located above the bottommost lead wire film layer in the laminated structure may include, in addition to the actual lead wire pattern portion 11, a virtual pattern portion 13. The virtual pattern portion 13 is overlapped with the at least one interconnection through hole and exposed in the vertical direction Z, so that the virtual pattern portion 13 and the interconnection conductor inside the at least one interconnection through hole overlap and connect in the vertical direction Z, that is to say, the interconnection conductor may penetrate through the virtual pattern portion 13 above the bottommost lead wire film layer to realize connection with the virtual pattern portion 13. It should be understood that the virtual pattern portion 13 of the present embodiment refers to a pattern portion that is not related to the circuit function in the multilayer connection structure, and mainly plays a role in the design of the entire multilayer connection structure to ensure uniformity and consistency of etching of each interconnection through hole.

In order to avoid the problems of leakage and short circuit, the virtual pattern portion 13 and the actual lead wire pattern portion 11 located in the same lead wire film layer need to be disconnected from each other. Specifically, the virtual pattern portion 13 and the actual lead wire pattern portion 11 may be isolated from each other by the insulating isolation portion 12 to make the virtual pattern portion 13 and the actual lead wire pattern portion 11 insulated from each other.

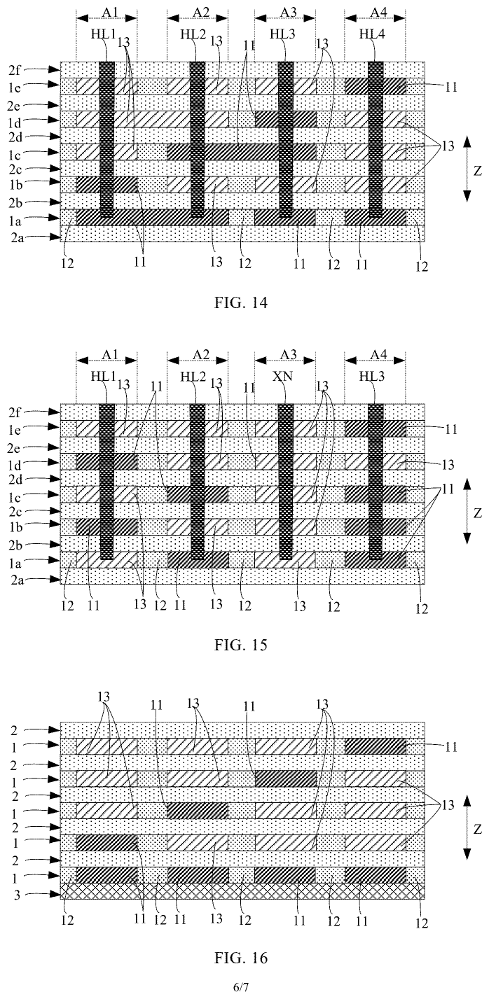

In some embodiments, referring to FIG. 14, the first interconnection conductor HL1 and the second interconnection conductor HL2 are connected together by the actual lead wire pattern portion 11 of the first lead wire film layer 1a, and the actual lead wire pattern portion 11 of the second lead wire film layer 1b to which the first interconnection conductor HL1 is connected is disconnected from the virtual pattern portion 13 of the second lead wire film layer 1b to which the second interconnection conductor HL2 is connected, but not limited to herein. When the first interconnection conductor HL1 and the second interconnection conductor HL2 are connected together by the actual lead wire pattern portion 11 of the first lead wire film layer 1a, and when the virtual pattern portion 13 of the second lead wire film layer 1b to which the second interconnection conductor HL2 is connected is not connected to the other virtual pattern portion 13, it is possible to make the actual lead wire pattern portion 11 of the second lead wire film layer 1b to which the first interconnection conductor HL1 is connected connect to the virtual pattern portion 13 of the second lead wire film layer 1b to which the second interconnection conductor HL2 is connected, so that the virtual pattern portion 13 of the second lead wire film layer 1b connected to the second interconnection conductor HL2 is formed as an actual pattern portion, and by designing the actual pattern portion in this manner, an effect of parallelly reducing impedance can be realized, and there is no need to disconnect the virtual pattern portion 13 of the second lead wire film layer 1b connected to the second interconnection conductor HL2 from the actual lead wire pattern portion 11 of the second lead wire film layer 1b connected to the first interconnection conductor HL1 by the patterning process, the process difficulty and process cost are reduced.

In the embodiments of the present disclosure, the virtual pattern portion 13 and the actual lead wire pattern portion 11 of the lead wire film layer where the virtual pattern portion 13 is located may be made simultaneously, for example, by first forming a conductor material film uniformly covered on the entire surface, and then patterning the conductor material film to form the virtual pattern portion 13 and the actual lead wire pattern portion 11 simultaneously, which not only makes the material of the virtual pattern portion 13 and the actual lead wire pattern portion 11 the same, but also makes the film thickness of the virtual pattern portion 13 and the film thickness of the actual lead wire pattern portion 11 the same. Specifically, in this embodiment, in the same lead wire film layer: the bottom surface of the virtual pattern portion 13 may be flush with the bottom surface of the actual lead wire pattern portion 11, and the top surface of the virtual pattern portion 13 (the surface is farthest away from the substrate required in the manufacturing process) may be flush with the top surface of the actual lead wire pattern portion 11 to ensure the flatness of the entire lead wire film layer and thus the flatness of the subsequent film layer.

In this embodiment, each interconnection through hole penetrates through the pattern portion of each lead wire film layer above the bottommost lead wire film layer in the vertical direction Z, and the pattern portion penetrated through by the interconnection through hole in the vertical direction includes the actual lead wire pattern portion 11 and/or the virtual pattern portion 13, so as to make each interconnection conductor to penetrate through the pattern portion of each lead wire film layer above the bottommost lead wire film layer in the vertical direction Z, and the pattern portions penetrated through by the interconnection conductor in the vertical direction Z include an actual lead wire pattern portion 11 and/or a virtual pattern portion 13.

For example, the laminated structure is first designed according to the actual situation, the design of the lead wire film layers in the laminated structure can be referred to FIG. 7, the first lead wire film layer 1a is provided with an actual lead wire pattern portion 11 in the first region A1, the second region A2, the third region A3, and the fourth region A4, respectively. The second lead wire film layer 1b is provided with an actual lead wire pattern portion 11 in the first region A1, and a virtual pattern portion 13 in the second region A2, A3 and the fourth region A4, respectively. The third lead wire film layer 1c is provided with the actual lead wire pattern portion 11 in the second region A2 and the virtual pattern portion 13 in the first region A1, the third region A3 and the fourth region A4, respectively. The fourth lead wire film layer 1d is provided with the actual lead wire pattern portion 11 in the third region A3, and the virtual pattern portion 13 in the first region A1, the second region A2 and the fourth region A4, respectively. The fifth lead wire film layer 1e is provided with the actual lead wire pattern portion 11 in the fourth region A4, and the virtual pattern portion 13 in the first region A1, the second region A2, and the third region A3, respectively.

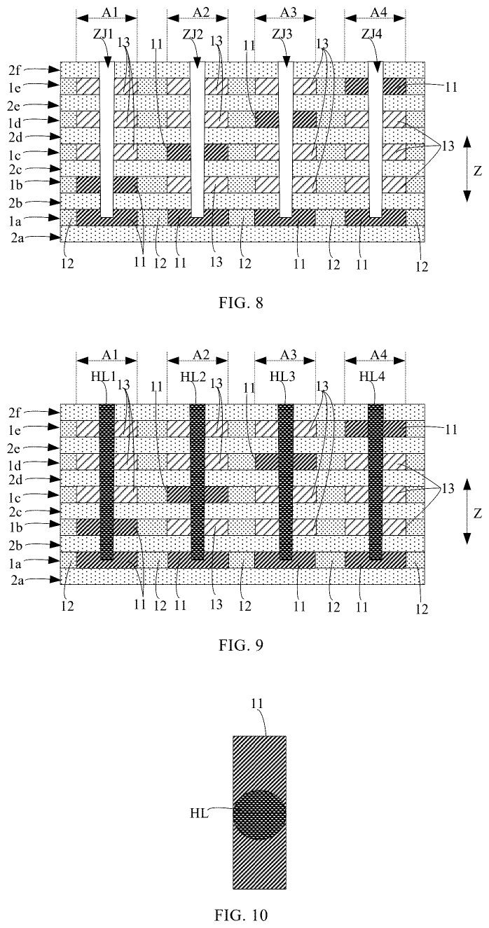

After forming the laminated structure as shown in FIG. 7, the laminated structure shown in FIG. 7 may be apertured to form the first interconnection through hole ZJ1 in the first region A1, the second interconnection through hole ZJ2 in the second region A2, the third interconnection through hole ZJ3 in the third region A3, and the fourth interconnection through hole ZJ4 in the fourth region A4. As shown in FIG. 8, the first interconnection through hole ZJ1, the second interconnection through hole ZJ2, the third interconnection through hole ZJ3, and the fourth interconnection through hole ZJ4 may penetrate through the pattern portion of each lead wire film layer above the bottommost lead wire film layer in the vertical direction Z, i.e., the first interconnection through hole ZJ1, the second interconnection through hole ZJ2, the third interconnection through hole ZJ3, and the fourth interconnection through hole ZJ4 may penetrate through pattern portions of the fifth lead wire film layer 1e, the fourth lead wire film layer 1d, the third lead wire film layer 1c, and the second lead wire film layer 1d in the vertical direction Z in turn, and the pattern portions penetrated through by the first interconnection through hole ZJ1, the second interconnection through hole ZJ2, the third interconnection through hole ZJ3, and the fourth interconnection through hole ZJ4 in the vertical direction Z include the actual lead wire pattern portion 11 and the virtual pattern portion 13.

It should be understood that the pattern portions penetrated through by the first interconnection through hole ZJ1, the second interconnection through hole ZJ2, the third interconnection through hole ZJ3, and the fourth interconnection through hole ZJ4 in the vertical direction Z are not limited to the foregoing mentioning that it includes the actual lead wire pattern portion 11, and also includes the virtual pattern portion 13, or it may include only the actual lead wire pattern portion 11, or only include the virtual pattern portion 13, which may be designed according to the actual situation, and it is only necessary to ensure that the pattern portions in the laminated film layer through which each interconnection through hole penetrates in the vertical direction Z are arranged in exactly the same position.

After preparing the first interconnection through hole ZJ1, the second interconnection through hole ZJ2, the third interconnection through hole ZJ3, and the fourth interconnection through hole ZJ4 shown in FIG. 8, the first interconnection through hole ZJ1, the second interconnection through hole ZJ2, the third interconnection through hole ZJ3, and the fourth interconnection through hole ZJ4 are filled with conductor material to form the first interconnection conductor HL1, the second interconnection conductor HL2, the third interconnection conductor HL3, and the fourth interconnection conductor HL4, respectively, shown in FIG. 9. The first interconnection conductor HL1, the second interconnection conductor HL2, the third interconnection conductor HL3, and the fourth interconnection conductor HL4 penetrate through the pattern portion of the fifth lead wire film layer 1e, the fourth lead wire film layer 1d, the third lead wire film layer 1c, and the second lead wire film layer 1d in the vertical direction Z. Preferably, the conductor material is filled in the first interconnection through holes ZJ1, the second interconnection through holes ZJ2, the third interconnection through holes ZJ3, and the fourth interconnection through holes ZJ4, which can reduce the interconnection impedance, and may improve the interconnection reliability.

In embodiments of the present disclosure, all interconnection through holes in the multilayer connection structure all penetrate through all film layers above the bottommost lead wire film layer in the laminated structure, that is, all interconnection through holes in the multilayer connection structure of the present disclosure are formed after the production of the topmost film layer of the laminated structure is completed, such design facilitates the simultaneous production of different types of interconnection conductors in the multilayer connection structure. Compared to the structural solution where different types of interconnection conductors need to be manufactured separately, the design of the multilayer connection structure of the present disclosure can reduce the number of processes and the number of masks used, thereby reducing the production cost of the multilayer connection structure and reducing the waste of production capacity.

Since all the interconnection through holes are formed after the production of the topmost film layer of the laminated structure is completed, it can be seen that in the present embodiment, the top surfaces of all the interconnection through holes are flush with each other, and referring to FIG. 8, the top surfaces of the first interconnection through hole ZJ1, the second interconnection through hole ZJ2, the third interconnection through hole ZJ3, and the fourth interconnection through hole ZJ4 are flush with each other.

In addition, in this embodiment of the present disclosure, through the design of the virtual pattern portion 13, it is possible to make laminated film layers penetrated through by each interconnection through hole in the vertical direction Z the same completely, thereby ensuring that each interconnection through hole has the same stopping position, e.g., with reference to FIG. 8, each interconnection through hole has the same stopping position located in the pattern portion of the first lead wire film layer 1a, which reduces the problem of under-etching or over-etching of part of the interconnection through holes, and then the stopping position of each interconnection conductor can be ensured to be the same, e.g., referring to FIG. 9, the stopping position of each interconnection conductor is located in the pattern portion of the first lead wire film layer 1a, thereby further ensuring that the interconnection conductors can be in contact with corresponding actual lead wire pattern portions 11.

In some embodiments, each interconnection through hole is not limited to penetrating through the pattern portion of each of the lead wire film layers above the bottommost lead wire film layer in the vertical direction Z, but may also penetrate through the pattern portion of the bottommost lead wire film layer, so that when the pattern portion of the bottommost lead wire film layer penetrated through is the actual lead wire pattern portion 11, the contact area of the interconnection conductor with the actual lead wire pattern portion 11 of the bottommost lead wire film layer can be increased, thereby ensuring that the contact stability and conductivity of the interconnection conductor with the actual lead wire pattern portion 11 in the bottommost lead wire film layer. In other words, the interconnection conductor of the present disclosure is not limited to the pattern portion of each of the lead wire film layers above the bottommost lead wire film layer in the vertical direction Z, but may also penetrate through the pattern portion of the bottommost lead wire film layer. It should be clarified that the pattern portion of the bottommost lead wire film layer penetrated through by the interconnection conductor may be the actual lead wire pattern portion 11, but is not limited thereto, and may also be the virtual pattern portion, which may be determined according to actual design requirements. When the etching rate of the pattern portion is lower than that of the insulation film layer 2 and the insulating isolation portion 12, the pattern portion of the bottommost lead wire film layer penetrated through by the interconnection conductor is set to be the virtual pattern portion, compared to setting the pattern portion of the bottommost lead wire film layer penetrated through by the interconnection conductors to be the insulating isolation portion 12, it can avoid the interconnection through hole corresponding to the interconnection conductors from damaging the film layers at lower upper of the laminated structure due to too large etching depth of the interconnection through hole.

In other embodiments, the stopping position of each interconnection through hole may also be located in the pattern portion of the bottommost lead wire film layer, that is to say, the bottom of each interconnection conductor (the end closest to the substrate required in the fabrication process) may be embedded in the pattern portion of the bottommost lead wire film layer, which can increase the contact area of the interconnection conductor with the actual lead wire pattern portion 11 of the bottommost lead wire film layer, thereby ensuring that the contact stability and electrical conductivity of the interconnection conductor with the actual lead wire pattern portion 11 of the bottommost lead wire film layer.

In other embodiments, each interconnection through hole may also stop at the top surface of the pattern portion of the bottommost lead wire film layer, so that the bottom surface of each interconnection conductor (the surface closest to the substrate required in the fabrication process) may just contact the top surface of the pattern portion of the bottommost lead wire film layer.

The multilayer connection structure designed with virtual pattern portions 13 in the present disclosure is not limited to the embodiments shown in FIGS. 7 to 9, but may also be adjusted according to the actual needs in terms of the number of layers of the lead wire film layers, the connection relationship of the actual lead wire pattern portions 11 among the lead wire film layers, and the design of the arrangement of the pattern portions in the lead wire film layers, and so on.

In other embodiments of the present disclosure, a plurality of laminated structures may be provided, and the plurality of laminated structures may be sequentially prepared and laminated in the vertical direction Z, at least some of the interconnection through holes/pattern portions are connected in the vertical direction Z to form a larger interconnection structure.

In some embodiments, as shown in FIGS. 2 to 5 and FIG. 9, the bottom surfaces of any of interconnection through holes may be flush with each other, and the top surfaces of any of interconnection through holes may be flush with each other, so that the bottom surfaces of any of interconnection conductors may be flush with each other, and the top surfaces of any of interconnection conductors may be flush with each other, that is, each interconnection conductor extends with the same length and the same extension start position and stop position, so as to ensure that each interconnection conductor can connect the corresponding actual lead wire pattern portion.

In some embodiments, with reference to FIGS. 2 to 5 and FIG. 9, the top surfaces of the interconnection conductors may be flush with the top surfaces of the laminated structure to ensure the flatness of the entire multilayer connection structure and to facilitate the design of the stacking with other film layer structures.

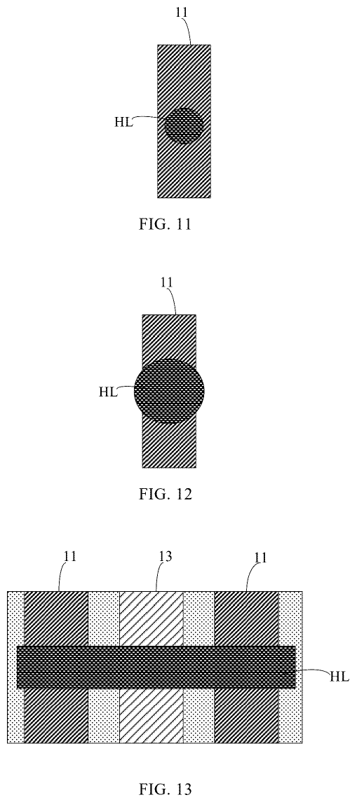

In some embodiments, the positive projection of the at least one interconnection through hole in the vertical direction Z is located entirely within one pattern portion of each lead wire film layer, so that the positive projection of the at least one interconnection conductor in the vertical direction Z is located entirely within one pattern portion of each lead wire film layer, and when satisfying the design requirements, the outer diameter of the interconnection conductor (i.e., the aperture diameter of the interconnection through hole to which the interconnection conductor corresponds) may be equal to the width of the corresponding pattern portion, e.g.: the outer diameter of the interconnection conductor HL shown in FIG. 10 is equal to the width of the corresponding actual lead wire pattern portion 11, but is not limited thereto, and may also be smaller than the width of the corresponding pattern portion, e.g.: the outer diameter of the interconnection conductor HL shown in FIG. 11 is smaller than the width of the corresponding actual lead wire pattern portion 11, so that when various places in the interconnection through hole in the same horizontal plane pass through the lead wire film layer, etched materials are all the same, i.e., they are all the materials of the pattern portions, thereby ensured that the interconnection through holes can be opened uniformly, in addition, such design can also prevent short-circuits or leakage caused by the contact of the interconnection conductors with the actual lead pattern portion 11 that does not need to be connected.

It should be noted that the reference to a horizontal plane in this embodiment refers to a plane perpendicular to the vertical direction Z.

In other embodiments, when the design requirements are satisfied, the aperture diameter of the interconnection through hole corresponding to the interconnection conductor may also be larger than the width of the corresponding pattern portion, e.g., the outer diameter of the interconnection conductor HL shown in FIG. 12 is larger than the width of the corresponding actual lead wire pattern portion 11. Thus, the aperture of the interconnection through hole can be enlarged, thereby reducing the difficulty of alignment of the pattern and the difficulty of controlling the etching process.

In some embodiments, the positive projection of at least one interconnection conductor in the vertical direction overlaps with a plurality of pattern portions in the same lead wire film layer, such design reduces the processing difficulty of the interconnection through hole corresponding to the interconnection conductor. For example, where the plurality of pattern portions in the same lead wire film layer includes a plurality of actual lead wire pattern portions 11 that need to be across-connected, as shown in FIG. 13, the actual lead wire pattern portion 11 on the left side needs to be spanned across the virtual pattern portion 13 in the middle to connect with the actual lead wire pattern portion 11 on the right side, and the interconnection conductor HL is utilized to achieve the across-correction of the two actual lead wire pattern portions 11.

In some embodiments, at least one pattern portion may be connected to a plurality of interconnection conductors, and the pattern portion may be an actual lead wire pattern portion 11 or a virtual pattern portion 13. By way of example, with reference to FIG. 14, the first lead wire film layer 1a may include one actual lead wire pattern portion 11, which spans across the first region A1 and the second region A2, and is connected to the first interconnection conductor HL1 and the second interconnection conductor HL2. The third lead wire film layer 1c may include an actual lead wire pattern portion 11 that spans across the second region A2 and the third region A3 and is connected to both the second interconnection conductor HL2 and the third interconnection conductor HL3, and the fourth lead wire film layer 1d may include a virtual pattern portion 13 that spans across the first region A1 and the second region A2 and is connected to both the first interconnection conductor HL1 and the second interconnection conductor HL2. As a result, the number of pattern portions in each lead wire film layer can be reduced when meeting the design requirements, so that the requirement for patterning accuracy can be reduced during patterning of the lead wire film layer, and thus the cost of the patterning process can be reduced.

It should be noted that the pattern portions connected to the plurality of interconnection conductors in the multilayer connection structure of the present disclosure are not limited to the positions shown in FIG. 14, and the number of the pattern portions connected to the interconnection conductors is not limited to two, but may be three, four, and so forth, depending on the specific design situation.

In other embodiments, the multilayer connection structure of the present disclosure, in addition to including the interconnection conductors having actual functions in a circuit as mentioned before, may include a virtual conductor XN spaced apart from the interconnection conductors as shown in FIG. 15, the virtual conductor XN is co-manufactured and molded together with the first interconnection conductor HL1, the second interconnection conductor HL2, and the third interconnection conductor HL3 as shown in FIG. 15, and the top and bottom of the virtual conductor XN are flush with the top and the bottom of the first interconnection conductor HL1, the second interconnection conductor HL2, and the third interconnection conductor HL3, respectively, and the number and the order of arrangement of pattern portions in the laminated film layers penetrated through by the virtual conductor XN are the same as those of the interconnection conductors. In a word, the main difference between the virtual conductor XN and the interconnection conductor is that at least one of the pattern portions connected to the interconnection conductor is that at least one of the pattern portions connected to the interconnection conductor is the actual lead wire pattern portion 11, whereas all of the pattern portions connected to the virtual conductor XN are virtual pattern portions 13, and the virtual conductor XN does not have any actual conductive function in the entire multilayer connection structure. The interconnection through holes corresponding to the virtual conductor XN can be used to even out the density of the interconnection through holes opened in each region, thereby avoiding etching morphological defects caused by variations in the etching density when etching the interconnection through holes, and after the virtual conductor XN is filled, the stability of the structure can be improved, and by configuring the virtual conductor XN and the patterns of the pattern portion connected to the virtual conductor XN, other non-conducting functions can be realized, such as shielding of interference of the interconnection members from each other, etc., which is not specifically limited in the present disclosure.

Embodiments of the present disclosure further provide a manufacturing method for manufacturing the multilayer connection structure referred to in any of the preceding embodiments, the manufacturing method of the present embodiment may include:

Step S100, alternately providing the lead wire film layer 1 and the insulation film layer 2 on the substrate 3 in the vertical direction Z to form a laminated structure, a plurality of the lead wire film layers 1 are provided, at least one insulation film layer 2 is provided, and each lead wire film layer 1 includes at least the actual lead wire pattern portion 11, e.g., the laminated structure shown in FIG. 16, it should be appreciated, however, that the laminated structure of the present embodiment is not limited to that shown in FIG. 16, and specific can be adjusted according to the actual design requirements.

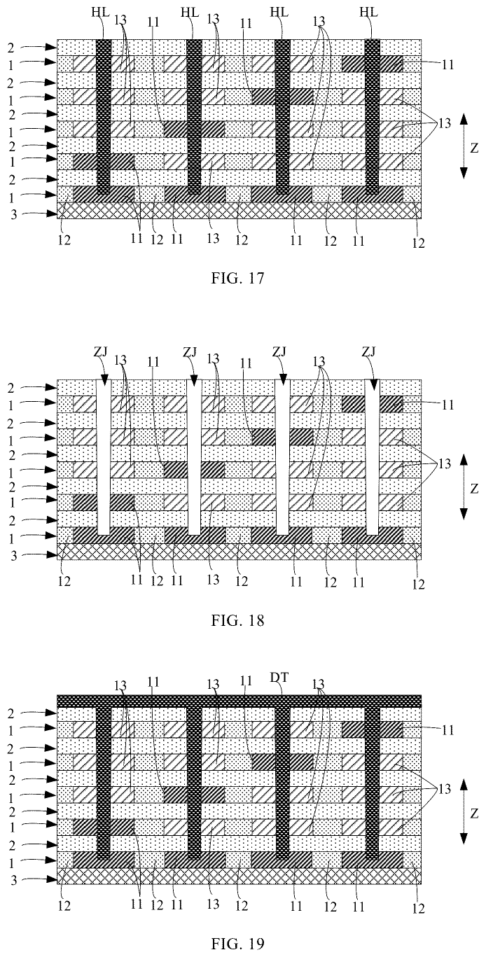

Step S200, after forming the topmost film layer of the laminated structure, forming a plurality of interconnection conductors HL, the interconnection conductors HL penetrate through at least all the film layers above the bottommost lead wire film layer 1 in the laminated structure and are connected to the actual lead wire pattern portion 11 of the at least one lead wire film layer 1, and the number of and/or positions in the lead wire film layer 1 where actual lead wire film layers 1 that at least two of the interconnection conductors HL are correspondingly connected to are located is not exactly the same, for example, the multilayer connection structure shown in FIG. 17, but it should be understood that the multilayer connection structure of the present embodiment is not limited to that shown in FIG. 17, which may be correspondingly adjusted according to actual design requirements.

In some embodiments, step S200, forming the plurality of interconnection conductors HL, may specifically include:

Step S201, patterning the laminated structure using an etching process to form a plurality of interconnection through holes ZJ spaced apart. The interconnection through holes ZJ penetrate through at least all the film layers above the bottommost lead wire film layer 1 in the laminated structure and expose the actual lead wire pattern portions 11 of at least one lead wire film layer 1, and positions in the lead wire film layers 1 where the actual lead wire pattern portions 11 exposed by at least two of the plurality of interconnection through holes ZJ are located are not totally identical, e.g., the intermediate structure shown in FIG. 18 for opening the interconnection through holes in the laminated structure, but it should be understood that the intermediate structure of the present embodiment is not limited to that shown in FIG. 18, and the specific interconnection structure may be correspondingly adjusted according to the actual design requirements;

Step S202, filling each interconnection through hole ZJ with a conductor material to form an interconnection conductor HL in each interconnection through hole ZJ, and the specific structure formed may be shown in FIG. 17.

For example, in step S202, a conductor material film DT may first be formed, the conductor material film DT includes the conductor material filled in each interconnection through hole ZJ, and also includes the conductor material covering the top surface of the laminated structure, as shown in FIG. 19, and then the conductor material on the top surface of the laminated structure may be removed to form a plurality of interconnection conductors HLs spaced apart, as shown in FIG. 17, without being limited to this. The conductor material on the top surface of the laminated structure may not be completely removed, but may also be partially retained to enable bridging of the plurality of interconnection conductors.

In some embodiments, in order to ensure uniformity in the opening of the interconnection through holes, as shown in FIG. 16, a virtual pattern portion 13 disconnected from the actual lead wire pattern portion 11 may be designed in the at least one lead wire film layer 1. As shown in FIG. 18, the interconnection through holes ZJ penetrate through the pattern portion of each of the lead wire film layers 1 above the bottommost lead wire film layer 1 in the vertical direction Z, and the pattern portion penetrated through by the interconnection through holes ZJ in the vertical direction Z includes an actual lead wire pattern portion 11 and/or a virtual pattern portion 13.

In an embodiment, the step of forming the lead wire film layer 1 including an actual lead wire pattern portion 11 and a virtual pattern portion 13, includes:
Step S1001, forming a conductive film on the substrate 3;
Step S1002, patterning the conductive film to form the actual lead wire pattern portion 11 and the virtual pattern portion 13.

In another embodiment, the step of forming the lead wire film layer 1 including the actual lead wire pattern portion 11 and the virtual pattern portion 13, includes:
Step S1003, forming a conductive film on the substrate 3;
Step S1004, patterning the conductive film using a one-time composition process to simultaneously form a portion of the actual lead wire pattern portion 11 and at least one intermediate pattern portion, the intermediate pattern portion being disconnected from the actual lead wire pattern portion 11;
Step S1005, patterning the intermediate pattern portion using the one-time composition process to simultaneously form another portion of the actual lead wire pattern portion 11 and the virtual pattern portion 13.

Embodiments of the present disclosure also provide a semiconductor device, which semiconductor device may be a Dynamic Random Access Memory (DRAM), but is not limited thereto, and may be other types of structures, such as, for example, a Front End Of Line, front end of line, front channel process (FEOL) semiconductor structure, or may be a back end of line (BEOL) semiconductor structure, which will not be exemplified herein.

In this embodiment, with reference to FIG. 17, the semiconductor device may include a substrate 3 and at least one multilayer connection structure, and the multilayer connection structure may be formed on the substrate 3, and the design scheme of the multilayer connection structure may be referred to in any of the foregoing embodiments, and will not be repeated herein. In some embodiments, the semiconductor substrate includes a substrate 3 and a plurality of multilayer connection structures, the plurality of multilayer connection structures may be horizontally distributedly formed on the substrate 3, or the plurality of multilayer connection structures may be vertically laminated on the substrate 3, depending on the design requirements.

The vertical direction Z may be a direction perpendicular or nearly perpendicular to the substrate 3 to reduce the difficulty of fabricating the multilayer connection structures.

In some embodiments, the substrate 3 may be a semiconductor substrate, but is not limited thereto, and may also be other types of substrates 3, depending on the specific situation.

It should be noted that a positive projection of the multilayer connection structure on the substrate 3 of the present embodiment may completely cover the substrate 3, but is not limited thereto, and may also be positively projected on a localized region of the substrate 3, depending on the design requirements.

Furthermore, the terms “first”, “second”, “third”, “fourth”, etc. are used for descriptive purposes only, and are not to be understood as indicating or implying relative importance or implicitly specifying the number of technical features indicated. As a result, features defined as “first”, “second”, “third”, “fourth” may expressly or implicitly include one or more technical features. In the description of the present disclosure, “more than one” means two or more, unless otherwise expressly limited.

In the description of the present specification, the description with reference to the terms “some embodiments”, “exemplarily”, etc. means that the specific features, structures, materials or characteristics described in conjunction with the embodiments or examples are included in at least one embodiment or example of the present disclosure. In this specification, schematic expressions of the above terms need not be directed to the same embodiment or example. Moreover, the specific features, structures, materials, or characteristics described may be combined in any one or more embodiments or examples in a suitable manner. Moreover, without contradicting each other, those skilled in the art may combine and combine different embodiments or examples and features of different embodiments or examples described in this specification.

Although the embodiments of the present disclosure have been shown and described above, it is understood that the above embodiments are exemplary and cannot be construed as a limitation of the present disclosure, and that those skilled in the art may make changes, modifications, substitutions and variations of the above embodiments within the scope of the present disclosure, so that any changes or modifications made in accordance with the claims and the specification of the present disclosure shall fall within the scope of the patent coverage of the present disclosure.

What is claimed is:

1. A multilayer connection structure, comprising:
a laminated structure, comprising a plurality of lead wire film layers and at least one insulation film layer, wherein the plurality of lead wire film layers and the at least one insulation film layer are alternately provided in a vertical direction, wherein each of the plurality of lead wire film layers comprises an actual lead wire pattern portion;
a plurality of interconnection through holes horizontally spaced apart, wherein the plurality of interconnection through holes expose the actual lead wire pattern portion of the at least one of the plurality of lead wire film layers, and positions of the lead wire film layers where actual lead wire pattern portions exposed by at least two of the plurality of interconnection through holes are located are not totally identical, wherein in the laminated structure, each of the plurality of interconnection through holes penetrates through at least all of film layers above a bottommost lead wire film layer; and
interconnection conductors, filled in the plurality of interconnection through holes.

2. The multilayer connection structure according to claim 1, wherein top surfaces of any of the plurality of interconnection through holes are flush with each other.

3. The multilayer connection structure according to claim 2, wherein top surfaces of the interconnection conductors are flush with a top surface of the laminated structure.

4. The multilayer connection structure according to claim 1, wherein at least one lead wire film layer above the bottommost lead wire film layer in the laminated structure further comprises a virtual pattern portion disconnected from the actual lead wire pattern portion, wherein in each lead wire film layer, a bottom surface of the virtual pattern portion is flush with a bottom surface of the actual lead wire pattern portion, and a top surface of the virtual pattern portion is flush with a top surface of the actual lead wire pattern portion; and
wherein the virtual pattern portion and at least one interconnection through hole are overlapped and exposed in the vertical direction.

5. The multilayer connection structure according to claim 4, wherein each of the plurality of interconnection through holes penetrate through a pattern portion of each lead wire film layer above the bottommost lead wire film layer in the vertical direction, and the pattern portion penetrated through by each interconnection through hole in the vertical direction comprises at least one of the actual lead wire pattern portion and the virtual pattern portion.

6. The multilayer connection structure according to claim 5, wherein bottom surfaces of any of the plurality of interconnection through holes are flush with each other;
wherein the plurality of interconnection through holes penetrate through the pattern portion of the bottommost lead wire film layer; or
a bottom of each of the plurality of interconnection through holes is embedded within the pattern portion of the bottommost lead wire film layer.

7. The multilayer connection structure according to claim 5, a positive projection of at least one interconnection through hole in the vertical direction is located entirely within the pattern portion of each lead wire film layer.

8. The multilayer connection structure according to claim 2, wherein a plurality of insulation film layers are provided, and a topmost film layer of the laminated structure is the insulation film layer; or
more than three lead wire film layers are provided.

9. The multilayer connection structure according to claim 5, wherein a positive projection of at least one interconnection through hole in the vertical direction is overlapped with at least one pattern portion of the lead wire film layer in the same layer as the at least one interconnection through hole.

10. The multilayer connection structure according to claim 5, wherein at least one pattern portion is exposed by the plurality of interconnection through holes.

11. A semiconductor device, comprising a substrate and at least one multilayer connection structure, wherein each multilayer connection structure is formed on the substrate;
wherein each multilayer connection structure comprises:
a laminated structure, comprising a plurality of lead wire film layers and at least one insulation film layer, wherein the plurality of lead wire film layers and the at least one insulation film layer are alternately provided in a vertical direction, and each of the plurality of lead wire film layers comprises an actual lead wire pattern portion;
a plurality of interconnection through holes horizontally spaced apart, wherein the plurality of interconnection through holes expose the actual lead wire pattern portion of the at least one of the plurality of lead wire film layers, and positions of the lead wire film layers where actual lead wire pattern portions exposed by at least two of the plurality of interconnection through holes are located are not totally identical, wherein each of the plurality of interconnection through holes penetrates through at least all of film layers above a bottommost lead wire film layer in the laminated structure; and
interconnection conductors, filled in the plurality of interconnection through holes.

12. The semiconductor device according to claim 11, wherein top surfaces of any of the plurality of interconnection through holes are flush with each other.

13. The semiconductor device according to claim 12, wherein top surfaces of the interconnection conductors are flush with a top surface of the laminated structure.

14. The semiconductor device according to claim 11, wherein at least one lead wire film layer above the bottommost lead wire film layer in the laminated structure further comprises a virtual pattern portion disconnected from the actual lead wire pattern portion, in each lead wire film layer, a bottom surface of the virtual pattern portion is flush with a bottom surface of the actual lead wire pattern portion, and a top surface of the virtual pattern portion is flush with a top surface of the actual lead wire pattern portion; and
wherein the virtual pattern portion and at least one interconnection through hole are overlapped and exposed in the vertical direction.

15. The semiconductor device according to claim 14, wherein each of the plurality of interconnection through holes penetrate through a pattern portion of each lead wire film layer above the bottommost lead wire film layer in the vertical direction, and the pattern portion penetrated through by each interconnection through hole in the vertical direction comprises at least one of the actual lead wire pattern portion and the virtual pattern portion.

16. The semiconductor device according to claim 15, wherein bottom surfaces of any of the plurality of interconnection through holes are flush with each other;
wherein the plurality of interconnection through holes penetrate through the pattern portion of the bottommost lead wire film layer.

17. The semiconductor device according to claim 15, wherein a positive projection of at least one interconnection through hole in the vertical direction is located entirely within the pattern portion of each lead wire film layer.

18. A method of manufacturing a multilayer connection structure, comprising:
alternately providing a lead wire film layer and an insulation film layer on a substrate in a vertical direction to form a laminated structure, wherein a plurality of lead wire film layers are provided, at least one insulation film layer is provided, and each of the plurality of lead wire film layers comprises an actual lead wire pattern portion;
after forming a topmost film layer of the laminated structure, patterning the laminated structure using an etching process to form a plurality of interconnection through holes horizontally spaced apart, wherein in the laminated structure, the plurality of interconnection through holes penetrate through at least all of film layers above a bottommost lead wire film layer and expose the actual lead wire pattern portion of at least one lead wire film layer, and positions of the lead wire film layers where actual lead wire pattern portions exposed by at least two of the plurality of interconnection through holes are located are not totally identical; and
filling each interconnection through hole with conductor material to form an interconnection conductor within each interconnection through hole.

19. The method according to claim 18, wherein the at least one lead wire film layer further comprises a virtual pattern portion disconnected from the actual lead wire pattern portion, and the interconnection through hole penetrates through the pattern portion of each lead wire film layer above the bottommost lead wire film layer in the vertical direction, and the pattern portion penetrated through by the interconnection through hole in the vertical direction comprises at least one of the actual lead wire pattern portion and the virtual pattern portion;
wherein forming the lead wire film layer comprising the actual lead wire pattern portion and the virtual pattern portion comprises:
forming a conductive film on the substrate; and
patterning the conductive film to simultaneously form the actual lead wire pattern portion and the virtual pattern portion.

20. The method according to claim 18, wherein the interconnection through hole penetrates through the pattern portion of each lead wire film layer above the bottommost lead wire film layer in the vertical direction, and the pattern portion penetrated through by the interconnection through hole in the vertical direction comprises the actual lead wire pattern portion and/or a virtual pattern portion;
wherein forming the lead wire film layer comprising the actual lead wire pattern portion and the virtual pattern portion comprises:
forming a conductive film on the substrate;
patterning the conductive film using a one-time composition process to simultaneously form a portion of the actual lead wire pattern portion and at least one intermediate pattern portion, wherein the intermediate pattern portion is disconnected from the actual lead wire pattern portion; and
patterning the intermediate pattern portion using the one-time composition process to simultaneously form another portion of the actual lead wire pattern portion and the virtual pattern portion.
